(19) United States
(12) Patent Application Publication
(10) Pub. No.: US 2020/0068720 A1
(43) Pub. Date: Feb. 27, 2020

(54) Electronic Device Having Attach Pads, an Antenna and/or an Inductor With Printed Palladium Thereon, and Methods of Making the Same

(71) Applicants: Mao TAKASHIMA, Cupertino, CA (US); Aditi CHANDRA, Los Gatos, CA (US)

(72) Inventors: Mao TAKASHIMA, Cupertino, CA (US); Aditi CHANDRA, Los Gatos, CA (US)

(21) Appl. No.: 16/612,044

(22) PCT Filed: May 7, 2018
(86) PCT No.: PCT/US2018/031350

§ 371 Date: Nov. 8, 2019

Related U.S. Application Data
(60) Provisional application No. 62/502,964, filed on May 8, 2017.

(51) Int. Cl. H05K 3/34; H01Q 1/22; H05K 3/12; H05K 1/02; C23C 18/30

(52) U.S. Cl. CPC H05K 3/3457; H01Q 1/2283; C23C 18/30; H05K 1/0237; H05K 3/125

(57) ABSTRACT

An electronic device and methods of manufacturing the same are disclosed. One method of manufacturing the electronic device includes forming an electrical device on a first substrate, depositing a passivation layer on the electrical device, printing a palladium-containing ink on exposed aluminum pads in or on the electrical device, converting the palladium-containing ink to a palladium-containing layer, and forming a conductive pad or bump on the palladium-containing layer. The passivation layer exposes the aluminum pads.

### RELATED APPLICATION(S)

This application claims priority to U.S. Provisional Pat. Appl. No. 62/502,964, filed May 8, 2017, incorporated herein by reference.

### FIELD OF THE INVENTION

The present invention generally relates to the field(s) of printed and/or thin film electronic devices, and in some embodiments, to wireless communications and wireless devices, and methods of manufacturing the same. Embodiments of the present invention pertain to radio frequency (RF and/or RFID), near field communication (NFC), high frequency (HF), very high frequency (VHF), ultra high frequency (UHF), and electronic article surveillance (EAS) tags or cards, sensors, and other devices having a layer of palladium or other similar metal or alloy printed on attach pads, and optionally, an antenna and/or inductor, to enable plated or printed bump formation. The present invention improves electrical connectivity and/or attachment of an integrated circuit and/or the antenna and/or inductor to other electrical circuitry in the tag or device.

### Discussion of the Background

For so-called “smart labels”, EAS tags, and NFC backplanes and antennas, etched aluminum foil on a plastic (e.g., PET) film is preferred from a cost standpoint due to the relatively low expense of such materials and of their processing. However, assembly techniques using aluminum are generally limited to techniques using stud bumps with an anisotropic conductive paste (ACP). Generally, it is relatively difficult to attach both discrete devices and an integrated circuit (IC) onto the same aluminum foil structure.

Solder may be used to attach both discrete devices and printed integrated circuits (PICs) onto a single backplane (e.g., a copper backplane, an aluminum backplane plated with copper, or a tin backplane). In general, solder is a relatively cheap material and is suitable for high-volume processing.

Typically, the stud bumping process is a bottleneck for ultra-high volume assembly. For example, hundreds of bump-forming machines may be required to provide a throughput on the order of millions of units per month. As a result, sheet level bumping (e.g., by plating or screen printing) may be a viable alternative.

In conventional plated bump processing, which is well established in Surface Mount Technology (SMT) equipment, pads having a relatively thick aluminum or aluminum alloy layer may be required. Such pads may not be compatible with certain high-volume processes (e.g., printing, roll-to-roll processing, etc.). For example, it may be difficult to form a printed bump on thick aluminum attach pads due to a native aluminum oxide that forms on the surface of the pads. In addition, the relatively small size of the bump results in small tolerances for the accuracy of the attach process, while high-speed attach machines, such as rotary attach heads, require relatively large (or “loose”) tolerances.

Palladium is a useful metal for forming electrical contacts. For example, palladium inks may be used for various purposes, such as to print a seed layer for electroless plating, or to form a metal silicide as a contact metal. However, its use in facilitating attachment of electrical conductors to relatively large and/or thick aluminum structures, such as those formed from aluminum foil, is not known.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

The present invention relates to printed and/or thin film electronic devices, more specifically wireless communications and wireless devices. Embodiments of the present invention pertain to wireless tags, sensor cards and other electronic devices having a selectively deposited (e.g., printed) layer of palladium or other similar metal or alloy on attach or connection pads (e.g., aluminum pads), or on an antenna and/or inductor, and methods of manufacturing and using the same. The wireless tags may comprise radio frequency (RF and/or RFID), near field communication (NFC), high frequency (HF), very high frequency (VHF), ultra high frequency (UHF), and electronic article surveillance (EAS) tags. The present invention facilitates plated or printed bump and/or pad formation, thereby improving electrical connectivity and/or attachment of an integrated circuit, antenna and/or inductor to metal trace(s) and/or other electrical circuitry in the tag or device.

In one aspect, the present invention relates to a method of manufacturing an electronic device, comprising forming an electrical device on a first substrate, depositing a passivation layer on the electrical device, printing a palladium-containing ink on exposed aluminum pads in the electrical device, converting the palladium-containing ink to a palladium-containing layer, and forming a conductive pad or bump on the palladium-containing layer. The passivation layer exposes the aluminum pads. The electronic device may be, in some cases, a wireless communication device.

In another aspect, the present invention relates to an electronic device, comprising a first substrate having an electronic device thereon, and a passivation layer on the electrical device. The electrical device has a plurality of exposed aluminum pads, and the passivation layer is configured to expose the aluminum pads. A printed palladium-containing layer is on the aluminum pads, and a conductive pad or bump is on the palladium-containing layer.

The present invention advantageously improves and/or enables various attachment techniques, such as plating or printing conductive bumps on or over aluminum attach pads having printed palladium thereon, and attaching the same to a backplane (which may be solder-available) using a conductive adhesive, low temperature solder, or self-assembly material. For example, a conductive, solid-phase bump (e.g., Ni) may be plated onto the aluminum attach pads, and the resulting bump may be attached to the backplane with a conductive epoxy. In other words, the present invention relates to use of a Pd ink to make an Al attach pad more compatible with various bump and attach techniques. The present invention advantageously enables formation of high-quality ohmic contacts to relatively thick aluminum layers and/or pads, as well as formation of relatively large pads or bumps on the aluminum layers and/or pads and the adjacent passivation layer, which allows larger tolerances during the attach process, further enabling use of an ultra-fast pick-and-place process. In addition, the present invention advantageously enables plated or printed bump formation, and improves the mechanical smoothness of an antenna and/or inductor and other metal trace(s), as well as the electrical contact between electronic devices (such as thin film and/or printed integrated circuitry) and the antenna, inductor, and/or trace. Furthermore, the present invention reduces the cost and processing time of certain electronic devices and/or wireless tags, such as smart labels and NFC, RF, HF, and UHF tags. These and other advantages of the present invention will become readily apparent from the detailed description of various embodiments below.

### BRIEF DESCRIPTION OF THE DRAWINGS

FIG. 1 shows a flow chart for an exemplary process for making an electronic device (e.g., a wireless communication device) having a printed palladium layer on aluminum attach pads in accordance with one or more embodiments of the present invention.

FIGS. 2A-2D show cross-sectional views of exemplary intermediates in an exemplary process, and FIG. 2E shows a cross-sectional view of an exemplary electronic device having a printed palladium layer on attach pads and/or an antenna, in accordance with one or more embodiments of the present invention.

FIGS. 3A-3B show plan and cross-sectional views of an exemplary antenna, and FIGS. 3C-D show plan and cross-sectional views of an exemplary electronic device having an attached antenna, in accordance with one or more embodiments of the present invention.

FIGS. 4A-4C are diagrams of exemplary circuits for use in various electronic devices according to the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and materials have not been described in detail so as not to unnecessarily obscure aspects of the present invention.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

The present invention advantageously enables plated or printed bump or pad formation on relatively thick aluminum layers or structures, reduces the roughness of an antenna and/or inductor or other metal trace(s) on a backplane, and improves the electrical contact between electronic circuitry and the antenna, inductor, and/or metal trace(s). The present invention advantageously provides forming the palladium-containing layer and the conductive pads or bumps without the need for thick layer aluminum pads. In addition, the present invention advantageously enables various high-throughput, large-tolerance attachment techniques using solid bumps and/or direct attachment to metal trace(s) and/or an antenna without the use of an organic copper protector (OCP) or anisotropic conductive paste (ACP). Furthermore, the present invention may reduce the cost and/or processing time of electronic devices and/or wireless tags, increase the scalability of the manufacturing process, and be compatible with food and other sensitive products.

An Exemplary Method of Making an Electronic Device

The present invention concerns a method of manufacturing an electronic device, comprising forming an electrical device on a first substrate, depositing a passivation layer on the electrical device, printing a palladium-containing ink on exposed aluminum pads in the electrical device, converting the palladium-containing ink to a palladium-containing layer, and forming a conductive pad or bump on the palladium-containing layer. The passivation layer exposes the aluminum pads. The electrical device may be an integrated circuit, an antenna or a capacitor. The electronic device may be a wireless communication device. In various embodiments, the wireless communication device may comprise a radio frequency (RF and/or RFID), near field communication (NFC), high frequency (HF), very high frequency (VHF), ultra high frequency (UHF), or electronic article surveillance (EAS) tag. In one example, the device is an NFC device, such as an NFC tag, smart tag, or smart label. Alternatively, the electronic device may be or comprise a sensor card, tag, label and/or device.

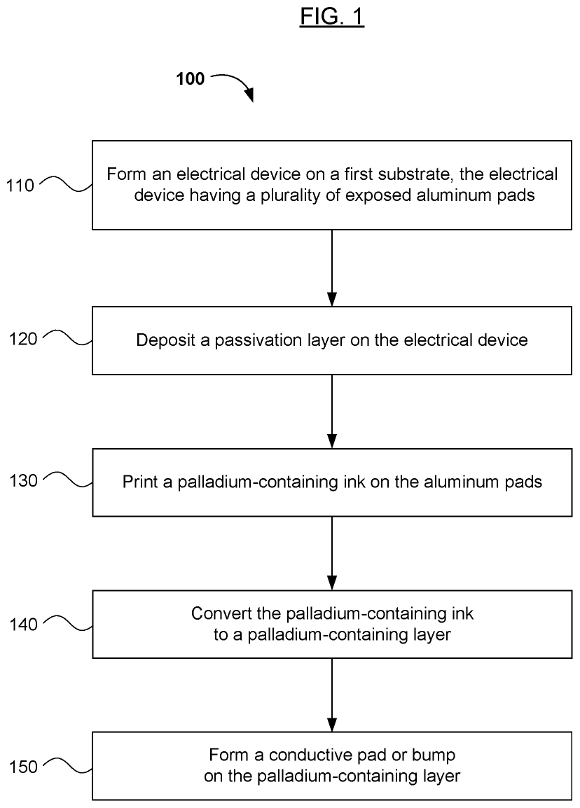

FIG. 1 shows a flow chart for an exemplary process 100 for making electronic devices (e.g., wireless communication devices, such as NFC/RF and/or EAS tags or devices) having a palladium-containing layer deposited on aluminum pads or an aluminum antenna, in accordance with one or more embodiments of the present invention. The palladium-containing layer advantageously improves and/or enables various attachment techniques, such as plating or printing solid bumps on or over the aluminum pads or on ends of the antenna, and attaching the same to a backplane (which may be solder-available) using a conductive adhesive, a low temperature solder, or a self-assembly material. The palladium-containing layer may be used to form larger conductive pads or bumps (e.g., on the aluminum pads and the adjacent passivation layer) to provide larger tolerances during the attach process and allow ultra-fast pick-and-place assembly processes.

At 110, an electrical device is formed on a first substrate. The electrical device may comprise an integrated circuit, an antenna or a discrete device/electrical component (e.g., capacitor, inductor, resistor, switch, etc.). The integrated circuit may comprise a thin film integrated circuit or a printed integrated circuit (e.g., excluding a circuit formed on a monolithic single-crystal silicon wafer or die). One or more layers of the integrated circuit (e.g., all of the layers of the integrated circuit) may include a thin film, or one or more layers of the integrated circuit (e.g., all of the layers of the integrated circuit) may be printed. For example, at least one layer may be a thin film, and at least one layer may be printed.

In various embodiments, the first substrate may comprise an insulative substrate (e.g., plastic film or glass). For example, the insulative substrate may comprise a polyimide, a glass/polymer laminate, or a high temperature polymer. The high temperature polymer may comprise or consist of polyethylene terephthalate [PET], polypropylene, or polyethylene naphthalate [PEN]. Alternatively, the first substrate may comprise a metal sheet, film or foil, or a laminate thereof. For example, the metal substrate may comprise a metal foil, such as a stainless steel foil, with one or more diffusion barrier and/or insulator films thereon. In one example, a stainless steel foil may have one or more diffusion barrier films such as a single or multilayer TiN, AlN, or TiAlN diffusion barrier film thereon, and one or more insulator films such as silicon dioxide, silicon nitride and/or silicon oxynitride on the diffusion barrier film(s). The diffusion barrier film(s) may have a combined thickness of from 300 Å to 5000 Å (e.g., 300-950 Å, or any thickness or range of thicknesses between 300 Å and 5000 Å), and the insulator film(s) may have a combined thickness of from 200 Å to 5000 Å (e.g., 250-2000 Å, or any thickness or range of thicknesses between 200 Å and 5000 Å). The insulator film(s) may have a thickness sufficient to electrically insulate electrical devices formed thereon from the underlying metal substrate and diffusion barrier layer(s).

Forming the integrated circuit or discrete device may comprise printing one or more layers of the integrated circuit or discrete device on the first substrate. An integrated circuit having one or more layers therein formed by printing may be considered to be a printed integrated circuit, or PIC. Alternatively, one or more layers may be formed by thin film processing.

In an exemplary method, a plurality of the layers of the integrated circuit may be printed, in which a lowermost layer (e.g., a lowermost insulator, conductor, or semiconductor layer) may be printed or otherwise formed on the first substrate. The lowermost layer of material is advantageously printed to reduce issues related to topographical variations in the integrated circuit layer(s) on the first substrate. Alternatively, a different (e.g., higher) layer may be printed. Printing offers advantages over photolithographic patterning processes, such as low equipment costs, greater throughput, reduced waste (and thus, a “greener” manufacturing process), etc., which can be ideal for relatively low transistor-count devices such as NFC, RF and

HF tags.

Alternatively, the method may form one or more layers of the integrated circuit by one or more thin film processing techniques. Thin film processing also has a relatively low cost of ownership, and is a relatively mature technology, which can result in reasonably reliable devices being manufactured on a wide variety of possible substrates. Thus, in some embodiments, the method may comprise forming a plurality of layers of the integrated circuitry by thin-film processing techniques (e.g., blanket deposition, photolithographic patterning, etching, etc.). In an alternative example, attach pads may be formed in an uppermost metal layer of the integrated circuit by thin-film processing.

In some embodiments, both printing and thin film processing can be used, and the method may comprise forming one or more layers of the integrated circuit by thin film processing, and printing one or more additional layers of the integrated circuit. In some embodiments, a plurality of integrated circuits may be formed on the first substrate, then singulated or otherwise separated prior to attachment to the antenna, metal trace(s), and/or inductor.

In various embodiments, the antenna may comprise a patterned aluminum layer (e.g., a patterned aluminum foil) on the first substrate. However, the antenna may comprise or consist essentially of another air-oxidizable metal. For example, the aluminum layer may consist essentially of elemental aluminum or may comprise or consist essentially of an aluminum alloy (e.g., aluminum with one or more alloying elements such as copper, titanium, silicon, magnesium, manganese, tin, zinc, etc.). Generally, the aluminum layer has a thickness of about from 3000 to 10,000 Å. In one example, the antenna may have a thickness of at least 10 μm. Generally, the antenna is configured to (i) receive and (ii) transmit or broadcast wireless signals.

In some embodiments, the antenna may consist of a single metal layer on the first substrate. An exemplary antenna thickness for HF devices may be about 20 μm to 50 μm (e.g., about 30 μm), and may be about 5 μm to about 30 μm (e.g., about 20 μm) for UHF devices. The antenna may be a spiral antenna having at least one loop (e.g., a plurality of loops). Alternatively, the antenna may have any of several forms, such as serpentine, sheet or block (e.g., square or rectangular), triangular, bowtie, etc.

In various embodiments, the antenna may be a printed antenna (e.g., formed from a printed conductor such as, but not limited to, silver or copper from a paste or nanoparticle ink, or from a foil or blanket-deposited metal such as aluminum, copper, tin, nickel, zinc, iron [e.g., steel], molybdenum, tungsten, etc. on which a resist mask is printed for subsequent etching) or a photolithographically-defined and etched antenna (e.g., formed by sputtering or evaporating aluminum or other metal on a substrate such as a plastic film or sheet, patterning by low-resolution [e.g., 10-1,000 μm line width] photolithography, and wet or dry etching using the patterned photolithography resist as a mask). The printed antenna may have a line with of from about 50 μm to about 5000 μm, and may have a morphology different from that of an otherwise identical photolithographically-defined and etched antenna or trace, a more rounded cross-section than an otherwise identical photolithographically-defined and etched antenna or trace, and/or a surface roughness, edge uniformity and/or line width uniformity that is generally greater than an otherwise identical photolithographically-defined and etched antenna or metal trace. The antenna may have a size and shape that matches any of multiple form factors, while preserving compatibility with the target frequency or a frequency specified by one or more industry standards (e.g., the 13.56 MHz target frequency of NFC reader hardware). In some embodiments, the antenna has a native oxide layer thereon, the native oxide layer having a thickness of 10-50 Å.

The discrete device (e.g., the capacitor or other discrete electrical component) may be printed or otherwise formed on the first substrate. When forming a capacitor, the method may comprise forming a first capacitor electrode or plate on the first substrate, forming a dielectric layer on or over the first capacitor electrode or plate, and forming a second capacitor electrode or plate on the dielectric layer. Details of forming capacitor structures by various techniques may be found in U.S. Pat. Nos. 7,152,804, 7,286,053, 7,387,260, and 7,687,327, and U.S. patent application Ser. No. 11/243,460, filed Oct. 3, 2005, the relevant portions of each of which are incorporated herein by reference.

The electrical device may have a plurality of exposed aluminum pads (e.g., attach or antenna connection pads) formed in or on an uppermost layer of the integrated circuit. The uppermost layer and/or the pads may be formed by a printing technique (e.g., screen printing, inkjet printing, gravure printing, etc.) or thin film processing. The aluminum pads may include a first aluminum pad (e.g., a first antenna connection pad) in a first location in the integrated circuit or at a first end of the antenna or discrete device, and a second aluminum pad (e.g., a second antenna connection pad) in a second location in the integrated circuit or at a second end of the antenna or discrete device. In the case of the antenna or discrete device, the second end may be at a location in the antenna or discrete device opposite from the first end. The aluminum pads in some cases may comprise input and/or output terminals (e.g., for signal transmission and/or reception). In various embodiments (e.g., of the antenna and discrete device), the aluminum pads are part of an aluminum foil. The aluminum pads also may include tungsten, copper, silver, etc., or a combination thereof, as an alloying element and/or as a separate layer. In some embodiments, the exposed aluminum pad may be formed by printing an aluminum ink on the integrated circuit. For example, the aluminum ink may comprise a source of aluminum, and optionally, a source of tungsten, copper, silver, or a combination thereof. Any organic residue remaining from the aluminum ink may be removed by plasma ashing.

At 120, a passivation or dielectric layer may be deposited on the electrical device (e.g., integrated circuit, antenna or capacitor). In various embodiments, the passivation layer may be formed by conventional deposition and photolithography. For example, the passivation layer may be formed by conventionally coating the upper surface of the integrated circuitry and/or device with one or more inorganic barrier layers such as a polysiloxane, a nitride, oxide or oxynitride of silicon and/or aluminum, and/or one or more organic barrier layers such as parylene, a fluorinated organic polymer, or other barrier material. In other embodiments, a photo-dielectric material may be used to form the passivation layer (e.g., by coating or blanket deposition, then irradiating and developing the photodielectric to pattern it).

In general, the passivation layer may include a polyimide, an epoxy, a silicon nitride or silicon oxynitride. The passivation layer may further comprise an underlying dielectric layer, which may comprise a material having lower stress than the overlying passivation layer. For example, the dielectric layer may comprise an oxide, such as SiO₂ (e.g., formed by chemical vapor deposition [CVD] of tetraethyl orthosilicate [TEOS]), undoped silicate glass [USG], a fluorosilicate glass [FSG], a borophosphosilicate glass [BPSG], etc.).

In some embodiments, the passivation layer may be blanket deposited and patterned by conventional photolithography and to etched to form the via holes over the aluminum pads. In other embodiments, the via holes may be formed by printing the passivation layer in a pattern that includes openings on or over the aluminum pads.

At 130, a palladium-containing ink is deposited on the aluminum pads. In various embodiments, the palladium-containing ink may be printed on the aluminum pads of the integrated circuit or discrete electrical component, or on ends of an antenna. The palladium-containing ink may comprise a solution of a palladium salt or complex or a suspension or emulsion of elemental palladium powder and/or palladium nanoparticles.

Palladium inks may be formulated in accordance with U.S. Pat. Nos. 8,617,992 and 8,066,805, the relevant portions of which are incorporated herein by reference. The palladium-containing ink may comprise one or more palladium salts and/or metal complexes, one or more solvents adapted to facilitate coating and/or printing of the formulation, and one or more optional additives that form gaseous or volatile byproducts upon reduction of the metal salt or metal complex to an elemental metal and/or alloy thereof. For example, the palladium ink may comprise palladium chloride, water, and a water-soluble solvent, such as tetrahydrofuran (THF), ethylene glycol, etc.

Suitable palladium salt(s) and/or complex(es) may have the formula PdXₙ or Pd(L)ₚXₙ, where X is a halide, pseudohalide, nitrate, sulfate, formate, acetate, other carboxylate anion (e.g., a C₁-C₂₀ carboxylate such as hexyldecanoate [HAD]), cyanate, isocyanate, alkoxide and/or diketonate, n is equal to the formal charge of palladium (e.g., two) plus any associated cations that are present, divided by the formal charge of X, L is selected from the group consisting of NH₃, H₂O, CO, NO, Na, H₂S, C₂H₄, C₆H₆, CN, NC, PH₃, PF₃, and volatile O- and/or N-containing organic solvents, and p is an integer equal to the number of coordination sites on Pd, minus the coordination sites occupied by Xₙ. In addition, the palladium-containing ink may also include an anion source additive, adapted to facilitate dissolution of the salt and/or metal complex in the solvent. The anion source may comprise, for example, NH₄X and/or HX, where X is chloride. The palladium salt and/or complex may form substantially only gaseous or volatile byproducts upon reduction of the salt and/or complex to palladium. The solvent may comprise H₂O, an organic solvent, a mixture of H₂O and one or more organic solvent(s), or a mixture of organic solvents.

Alternatively, the palladium ink may comprise palladium nanoparticles suspended in one or more organic solvents. Also, the palladium-containing ink may be commercially available (e.g., “Pre-cursor Catalytic Ink” from Averatek, Santa Clara, Calif.).

In exemplary embodiments, the palladium-containing ink is printed in a pattern on a surface of the aluminum pads or on the ends of the aluminum antenna. Processes for printing the palladium ink may include ink jet printing or gravure printing, screen printing, offset printing, extrusion coating, or combinations thereof. Alternatively, the palladium-containing ink may be printed on the surface of the aluminum pad and the surrounding passivation area continuously, forming a redistribution layer. Thus, the printed palladium pattern may extend on and/or over the passivation layer. The palladium-containing layer may have a thickness of 3 Å to 200 Å, or any thickness or range of thicknesses therein.

At 140, the palladium-containing ink may be converted to a palladium-containing layer. In one embodiment, the printed palladium-containing ink may be dried and cured. In general, when the present method comprises printing the palladium-containing ink, the method further comprises drying (or removing the solvent[s] from) the printed palladium-containing ink. In an exemplary embodiment, the drying process comprises heating the printed palladium-containing ink to a temperature and/or for a length of time sufficient to remove substantially all of the solvent(s). In other embodiments, drying comprises removing the solvent(s) in a vacuum, with or without applied heat. In any such embodiments, the temperature for removing the solvent may be from 30° C. to 150° C., 50° C. to 100° C., or any value or range of values therein. The length of time may be sufficient to remove substantially all of the solvent and/or substantially all of any additive(s) from the printed palladium-containing ink (e.g., from 1 minute to 4 hours, 5 minutes to 120 minutes, or any other range of values therein). The vacuum may be from 1 mtorr to 300 torr, 100 mtorr to 100 torr, 1-20 torr, or any other range of values therein, and may be applied by vacuum pump, aspirator, Venturi tube, etc. Such additives may be selected from those additives that can be removed substantially completely by heating at a temperature of from room temperature to 150° C. and/or under a vacuum of from 1 mtorr to 1 atm for a length of time of from 1 minute to 8 hours, such as water, HCl, ammonia, tetrahydrofuran, glyme, diglyme, etc.

After printing and drying the palladium-containing ink, the printed palladium-containing layer may be reduced by various methods. For example, the printed palladium-containing layer may be exposed to a reducing agent and heated at a temperature ranging from greater than ambient temperature to about 200-400° C., depending on the substrate. Such a process has particular advantages when the substrate must be processed at a relatively low temperature (e.g., when the substrate is or comprises aluminum foil, a polycarbonate, polyethylene, polypropylene, a polyester, a polyimide, etc.). A sealable oven, furnace, or rapid thermal annealing furnace configured with a vacuum source and reducing/inert gas sources may be used for providing the reducing atmosphere and heat (thermal energy) for heterogeneous reduction. In the alternative, the palladium-containing film may be thermally decomposed to the elemental metal using a heat source (e.g., a hotplate) in an apparatus in which the atmosphere may be carefully controlled (e.g., a glove box or dry box). In further embodiments, the palladium-containing ink or precursor may be reduced in a liquid (e.g., using hydrazine in water and/or an organic solvent, or a solution of a borane, a borohydride, an aluminum hydride [e.g., LiAlH₄], etc.) or in an atmosphere comprising a reducing agent in the form of a vapor, gas, or plasma source (e.g., forming gas, ammonia, hydrazine vapor, a hydrogen plasma, etc.).

Curing (e.g., by annealing) a palladium salt or complex in a palladium ink generally includes heating or baking the dried ink in a reducing atmosphere under forming gas at a temperature of 100° C. to 250° C., preferably at a temperature of 100-150° C. For example, in one variation, the annealing temperature for forming palladium from the dried palladium precursor (e.g., in the ink) may range from 120 to 300° C. (e.g., from about 150 to about 250° C., or any temperature or range of temperatures therein). However, with possible improvements in purity, print processing, film morphology, etc., the annealing temperature for forming metal having relatively higher conductivity can be reduced to less than 100° C., and possibly even at ambient temperatures (e.g., about 25° C.).

At 150, a conductive pad or bump may be formed on the palladium-containing layer. The conductive pad or bump comprises a second metal layer (e.g., a bonding metal or alloy, such as Ni, Cu, Sn, Ti, Ta, Hf, W, alloys thereof, solders for solder bumps, etc.). The second metal layer may be printed or electrolessly plated on the palladium-containing layer. For example, the palladium-containing layer may be plated with a second metal layer such as nickel, copper, tin, silver, gold, or a combination thereof. The second metal layer adheres to the palladium-containing layer and forms a strong bond to or with subsequently-attached electrical connectors. The second metal layer may also form an alloy or intermetallic interface with the palladium layer. In addition, relatively large attach pads may be formed to attach the device using solder or a self-assembly material (e.g., SAM10 resin, Tamura Corp., Tokyo, JP).

In the electroless plating process, the palladium-containing layer may be dipped in a copper or nickel electroless plating bath at about 40° C., rinsed with distilled water, then subsequently dipped in an immersion gold or tin bath. The second metal may then be annealed at a temperature of 100-150° C. (e.g., at about 130° C.) for approximately 5-15 minutes (e.g., for approximately 10 minutes). The electroless nickel or copper are then plated on the palladium pattern at a thickness that enables the attach method. The immersion gold or tin plating advantageously prevents the pad or bump from degradation (e.g., oxidation).

Alternatively, the conductive pad or bump (e.g., a solder bump) may be printed on top of the palladium-containing layer to form an ohmic contact between the aluminum pad and the bump. The printed bump may be or comprise solder, silver, etc. In some embodiments, the bump may be diced with a laser. The solder bumps may include a solder alloy (e.g., tin and one or more alloying elements), and may be deposited or printed (e.g., by screen printing) on the palladium-containing layer(s). The alloying element(s) may be selected from bismuth, silver, copper, zinc, and indium. The solder bumps may further contain an adhesive resin that may be activated by heating (e.g., to the solder reflow temperature or less), such as an epoxy resin. Some materials that include both a solder alloy and a resin include a SAM resin (e.g., SAM10 resin, available from Tamura Corporation, Tokyo, JP) and/or self-alignment adhesives with solder (SAAS) and/or SAM resins that are commercially available from Panasonic Corporation, Tokyo, JP; Namics Corporation, Niigata City, JP; and Nagase & Co., Ltd., Tokyo, JP.

Additionally or alternatively, a bump having a relatively small area may be formed on the palladium layer formed from the palladium ink to attach an integrated circuit or discrete device to a backplane or an antenna. The integrated circuit or discrete device may be attached to a backplane or an antenna using a conductive epoxy or an anisotropic conductive paste (ACP) and a thermohead device.

The present invention advantageously forms the palladium-containing layer and the conductive pads or bumps on a thick aluminum pad and/or layer. The palladium-containing layer and the conductive pads or bumps may be extended to form large contact pads on top of the aluminum pad or layer and surrounding passivation layer, which allows a relatively large tolerance during the attach process, such as a pick and place process.

When the electrical device is the integrated circuit or discrete device, ends of an antenna may be connected to palladium-containing layer and/or to the conductive pads or bumps on the integrated circuit or discrete device. Forming the antenna may comprise depositing or otherwise forming an aluminum layer (e.g., an aluminum foil) on a second substrate. The aluminum layer may be coated or laminated on the second substrate (e.g., to form a wireless backplane), then etched to form the antenna. Generally, the aluminum layer has a thickness of at least 10 μm. The aluminum layer can also include an aluminum alloy (e.g., with 0.1-5 wt. or atomic % of one or more of copper, tin, silicon, titanium, etc.). In alternative embodiments, at least one trace is formed on the second substrate instead of or in addition to an antenna. Typically, a plurality of metal traces are formed on the second substrate. Forming the antenna may also comprise etching the coated or laminated aluminum layer to form the antenna and/or one or more traces (e.g., on the backplane). Generally, the antenna and/or inductor is configured to (i) receive and (ii) transmit or broadcast wireless signals, and the trace(s) are configured to electronically connect an electrical device (e.g., an integrated circuit or discrete electrical component, such as a capacitor) to one or more other components (e.g., a battery, display, one or more sensors, etc.).

In some embodiments, forming the antenna and/or metal trace(s) may consist of forming a single metal layer on the first or second substrate, patterning the metal layer, and etching the single metal layer to form the antenna and/or metal trace(s). Alternatively, forming the antenna and/or metal trace(s) may comprise printing an ink or paste (e.g., including a third metal or metal precursor) on the first or second substrate in a pattern corresponding to the antenna and/or metal trace(s), then drying the ink or paste, and curing the metal or metal precursor in the ink or paste. Optionally, after printing, the method may further include reducing the metal precursor (such as a metal salt or complex) in the metal ink (e.g., by curing the metal salt or complex in a reducing atmosphere, such as forming gas). Additionally or alternatively, the method may include printing a metal seed layer by the printing process described herein this paragraph, and electroplating or electrolessly plating a bulk metal on the printed metal seed layer. An exemplary antenna and/or inductor thickness for HF devices may be about 20 μm to 50 μm (e.g., about 30 μm), and may be about 5 μm to about 30 μm (e.g., about 20 μm) for UHF devices.

When the antenna or metal traces are formed on the first or second substrate, a sensor, a battery and/or a display may be attached to one or more of the traces (as may the IC) and electrically connected to the electrical device via the palladium layer and/or the conductive pad and/or bump. In some embodiments, the antenna and/or the metal trace(s) may comprise a printed or coated bonding metal (e.g., palladium) on bonding surfaces thereof, which may make the antenna and/or metal traces solder-available. For example, the integrated circuit or discrete device (e.g., an EAS capacitor with solder bumps on aluminum connection pads) may be attached to a solder-available antenna using a reflow conveyer oven, thus eliminating any thermohead process. In various examples, the printed integrated circuit may be attached to the antenna using a printed solder (e.g., the bonding metal) in a reflow solder process at 160° C. Thus, the printed integrated circuit or EAS device may be attached to the backplane and/or antenna using a solder method. Furthermore, other components, such as the sensor, battery, and/or display, may be attached to traces on the substrate and/or to the antenna using any of a variety of solder or bump-and-attach methods.

In various embodiments, the second substrate may comprise an insulative substrate (e.g., a plastic film or glass). For example, the insulative substrate may comprise a polyimide, a glass/polymer laminate, or a high temperature polymer. The high temperature polymer may consist of polyethylene terephthalate [PET], polypropylene, or polyethylene naphthalate [PEN]. Alternatively, the second substrate may comprise a metal foil having one or more barrier and/or insulator layer(s), as described herein.

Exemplary Electronic Devices and Intermediates in an Exemplary Process for Manufacturing the Same

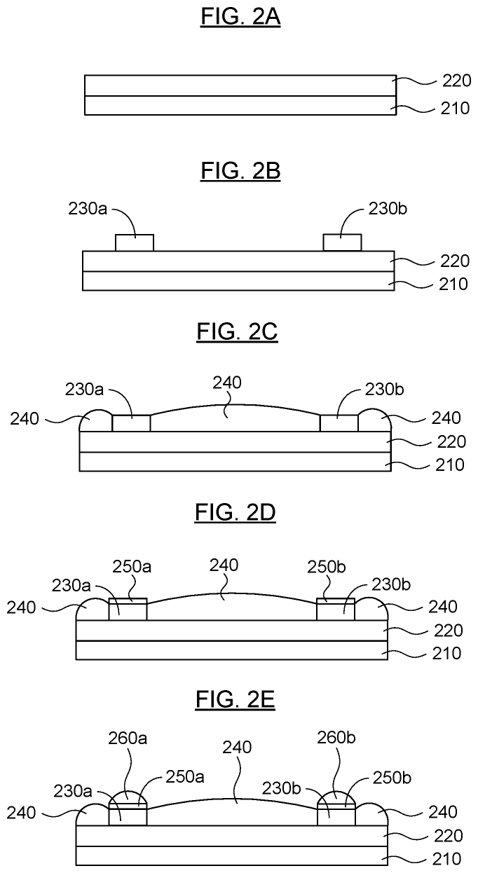

FIGS. 2A-2D show cross-sectional views of exemplary intermediates in an exemplary process, and FIG. 2E shows a cross-sectional view of an exemplary electronic device having a printed palladium-containing layer on aluminum pads and/or an antenna, in accordance with one or more embodiments of the present invention.

FIG. 2A shows a first substrate 210 having an electrical device 220 thereon. In various embodiments, the first substrate 210 may comprise an insulative substrate (e.g., a plastic film or glass). For example, the insulative substrate 210 may comprise a polyimide, a glass/polymer laminate, or a high temperature polymer. The high temperature polymer may comprise or consist of polyethylene terephthalate [PET], polypropylene, or polyethylene naphthalate [PEN], for example, but is not limited thereto. In other embodiments, the first substrate 210 comprises a metal foil. In one example, the metal foil may comprise a stainless steel foil, as described herein. Alternatively, the metal foil may comprise an aluminum foil, a tin foil, a molybdenum foil, a titanium foil, a copper foil, etc. When the first substrate 210 is a metal foil, it may be coated with one or more diffusion barrier and/or insulator layer(s), as described herein.

The electrical device 220 includes an integrated circuit or a discrete device. In various embodiments, when the electrical device 220 is a wireless communication device that includes the integrated circuit, the integrated circuit may comprise a receiver and/or a transmitter. The transmitter may comprise a modulator configured to generate a wireless signal to be broadcast by the assembled electronic device, and the receiver may comprise a demodulator configured to convert the wireless signal received by the assembled electronic device to one or more electrical signals (e.g., to be processed by the electrical device 220) and/or a rectifier configured to extract power from the received wireless signal.

In some embodiments, the electrical device 220 may include one or more printed layers. Such layers have characteristics of printed materials, such as greater dimensional variability, a thickness that varies (e.g., increases) as a function of the distance from the edge of the printed structure, a relatively high surface roughness, etc. Additionally and/or alternatively, the integrated circuit 220 may (further) comprise one or more thin films (e.g., a plurality of thin films).

Alternatively, the electrical device 220 may comprise or consist of a discrete device, as described herein. The discrete device may be or comprise a capacitor, a resistor, a switch, an inductor, etc. For example, the capacitor may comprise a first capacitor electrode or plate, a dielectric layer on the first electrode or plate, and a second capacitor electrode or plate on the dielectric layer. Alternatively, the capacitor may comprise first and second electrodes or plates with the dielectric therebetween.

As shown in FIG. 2B, the electrical device 220 further includes a plurality of attach or connection pads (e.g., aluminum pads) 230a-b. The pads 230a-b may be on or in an uppermost metal layer of the integrated circuit or discrete device. In exemplary embodiments, the uppermost metal layer of the electrical device 220 includes the aluminum pads 230a-b. If the electrical device 220 is a discrete device, the discrete device may include aluminum pads 230a-b electrically connected to electrodes or electrode terminals of the discrete device. Alternatively, the first and second aluminum pads 230a-b as shown may be first and second ends of an antenna, in which case the electrical device 220 is absent. The aluminum pads 230a-b comprise aluminum, and optionally, tungsten, copper, silver, or a combination thereof.

As shown in FIG. 2C, a passivation or dielectric layer 240 is deposited on the electrical device (e.g., integrated circuit, antenna or capacitor) 220. In various embodiments, the passivation layer 240 may be formed by conventional deposition and photolithography. For example, the passivation layer 240 may be formed by conventionally coating the upper surface of the integrated circuitry and/or device 220 with one or more inorganic barrier layers (not shown) such as a polysiloxane, a nitride, oxide or oxynitride of silicon and/or aluminum, and/or one or more organic barrier layers such as parylene, a fluorinated organic polymer, or other barrier material. In other embodiments, a photo-dielectric material may be use to form the passivation layer 240 (e.g., by coating or blanket deposition, then irradiating and developing the photodielectric to pattern it over the aluminum pads 230a-b).

In general, the passivation layer 240 may include a polyimide, an epoxy, a silicon nitride or silicon oxynitride. The passivation layer 240 may further comprise an underlying dielectric layer (not shown), which may comprise a material having lower stress than the overlying passivation layer 240. For example, the dielectric layer may comprise an oxide, such as SiO2 (e.g., formed by chemical vapor deposition [CVD] of tetraethyl orthosilicate [TEOS]), undoped silicate glass [USG], a fluorosilicate glass [FSG], a borophosphosilicate glass [BPSG], etc.). Via holes are formed in the passivation layer 240 on or over the aluminum pads 230, as described herein.

FIG. 2D shows a palladium-containing layer 250a-b on the aluminum attach or connection pads 230a-b. In exemplary embodiments, the palladium-containing layer 250a-b may be printed or otherwise selectively deposited on the pads 230a-b. Alternatively or additionally, the palladium-containing layer 250a-b may be on the aluminum pads 230a-b and the passivation layer 240 near or adjacent to the attach pads 230a-b. In such a case, the palladium-containing layer 250a-b may form a redistribution layer.

As shown in FIG. 2E, a second metal layer 260a-b (e.g., a conductive pad/bump or solder bump) may be formed on the palladium-containing layer 250a-b. The second metal layer 260a-b may comprise a bonding metal, such as nickel, copper, tin, silver, gold, or an alloy or combination thereof. In exemplary embodiments, the second metal layer 260a-b may include solder bumps. The solder bumps 260a-b may be electrolessly plated or printed bumps. Solder bumps 260a-b may include a solder alloy (e.g., tin and one or more alloying elements as described herein). For example, the alloying elements may be selected from bismuth, silver, copper, zinc, and indium.

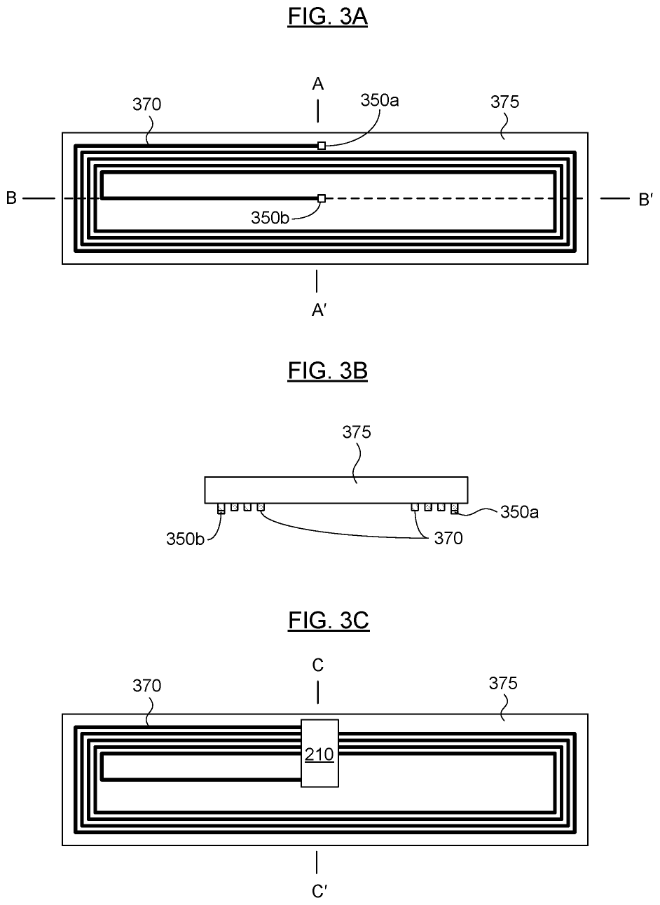

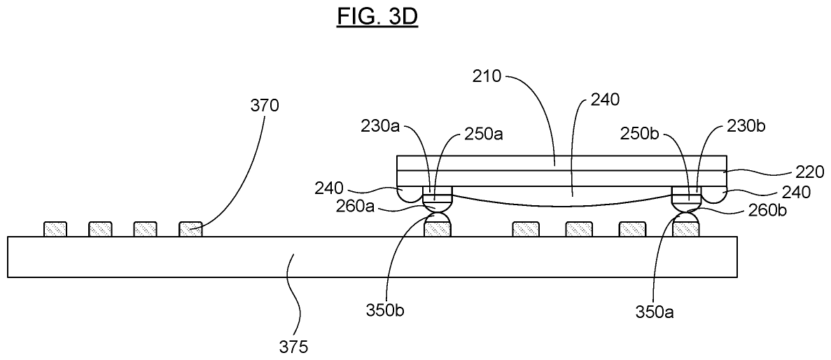

FIGS. 3A-3B show plan and cross-sectional views of an exemplary antenna, respectively, and FIGS. 3C-D show plan and cross-sectional views of an exemplary electronic device having an attached antenna, respectively, in accordance with one or more embodiments of the present invention.

FIG. 3A shows an antenna and/or inductor 370 on a second substrate 375. The antenna and/or inductor 370 is configured to (i) receive and (ii) transmit or broadcast wireless signals. In various embodiments, the antenna 370 may comprise a patterned aluminum layer (e.g., a patterned aluminum foil) on the second substrate 375. The aluminum layer may consist essentially of elemental aluminum or may comprise or consist essentially of an aluminum alloy (e.g., aluminum with one or more alloying elements such as copper, titanium, silicon, magnesium, manganese, tin, zinc, etc.). Generally, the aluminum layer 370 has a thickness of at least 10 μm. In addition, first and second ends of the aluminum layer 370 may be coated with a palladium layer 350a-b formed from the same or different palladium-containing ink, as that used to form the palladium layer 250a-b in FIG. 2D.

Generally, the antenna and/or inductor 370 is configured to (i) receive and (ii) transmit or broadcast wireless signals. Alternatively, the antenna and/or inductor 370 absorbs part of an electromagnetic signal broadcast from a radiation source (such as a wireless reader) and/or backscatters electromagnetic radiation from such a radiation source at a different wavelength. In some embodiments, the antenna and/or inductor 370 may consist of a single metal layer on the second substrate 375. An exemplary antenna and/or inductor thickness for HF devices may be about 20 μm to 50 μm (e.g., about 30 μm), and may be about 5 μm to about 30 μm (e.g., about 20 μm) for UHF devices. The antenna 370 may be a spiral antenna having at least one loop (e.g., a plurality of loops). Alternatively, the antenna 370 may have any of several forms, such as serpentine, sheet or block (e.g., square or rectangular), triangular, bowtie, etc.

In various embodiments, the antenna and/or inductor 370 may be a printed antenna and/or inductor (e.g., formed from a printed conductor such as, but not limited to, silver or copper from a paste or nanoparticle ink) or a photolithographically-defined and etched antenna and/or inductor (e.g., formed by sputtering or evaporating aluminum on a substrate such as a plastic film or sheet, patterning by low-resolution [e.g., 10-1,000 μm line width] photolithography, and wet or dry etching using the patterned photolithography resist as a mask). The printed antenna and/or inductor 370 may have a line with of from about 50 μm to about 5000 μm, and may have a morphology different from that of an otherwise identical photolithographically-defined and etched antenna or trace, a more rounded cross-section than an otherwise identical photolithographically-defined and etched antenna or trace, and/or a surface roughness, edge uniformity and/or line width uniformity that is generally greater than an otherwise identical photolithographically-defined and etched antenna or metal trace. The antenna and/or inductor 370 may have a size and shape that matches any of multiple form factors, while preserving compatibility with the target frequency or a frequency specified by one or more industry standards (e.g., the 13.56 MHz target frequency of NFC reader hardware).

In some embodiments, at least one trace (not shown) is also on the second substrate 375. A sensor, a battery and/or a display may be attached to one or more of the traces (typically, a plurality of traces) that is or are electrically connected to the electrical device 220 of FIGS. 2A-E. The traces may further comprise the palladium-containing layer 250a-b of FIGS. 2A-E on bonding surfaces thereof. The sensor may be configured to sense an environmental parameter, such as temperature or relative humidity, or a continuity state of packaging onto which the backplane (not shown), electrical device 220, and sensor are attached. The display may be a relatively simple monochromatic display, configured to display relatively simple data (e.g., a 2- or 3-digit number corresponding to the sensed parameter) and/or one of a limited number of messages (e.g., “Valid” or “Not Valid,” depending on the value of the parameter relative to a predetermined minimum or maximum threshold, or “Sealed” or “Open,” depending on the continuity state of the packaging). Furthermore, other components in addition to the sensor, battery, and/or display may be attached to the substrate and/or the palladium-plated attach pads 230/250 or the palladium-plated attach pads 230/250 and palladium-plated antenna 370 using any of a variety of surface mount technology (SMT) techniques.

Although FIGS. 3A-3B show a spiral antenna having four loops, the antenna may more than four loops or less than four loops, and may have any of several forms, such as serpentine, sheet or block (e.g., square or rectangular), triangular, etc. FIG. 3B shows a cross-section of the second substrate 375 along line A-A′ in FIG. 3A. The antenna 370 is deposited and etched or printed on the second substrate 375.

Optionally, the exemplary palladium layer 350a-b is also on the antenna 370. Preferably, the palladium layer 350a-b is printed or otherwise selectively deposited on at least the ends of the antenna 370.

FIG. 3C shows the electrical device 220 (FIGS. 2A-2E) attached face-down to the ends of the antenna 370 through the conductive pads or bumps 260a-b. The first substrate 210 (see, e.g., FIGS. 2A-2E) has the electrical device 220 and palladium-containing layer 250a-b on the pads 230a-b, as described above.

FIG. 3D shows a cross-section of the device of FIG. 3C along the C-C′ line. The electrical device 220 on the first substrate 210 is connected to the antenna and/or inductor 370 on the second substrate 375 through the aluminum pads 230a-b and the palladium-containing layer 250a-b and the second metal layer (e.g., conductive pads or bumps) 260a-b. In exemplary embodiments, the electrical device 220 is connected to the palladium-plated antenna 350a-b/370 through the palladium-plated attach pads 230a-b/250a-b and the conductive pads or solder bumps 260a-b thereon.

### Exemplary EAS Tags, Wireless Devices, and Sensors

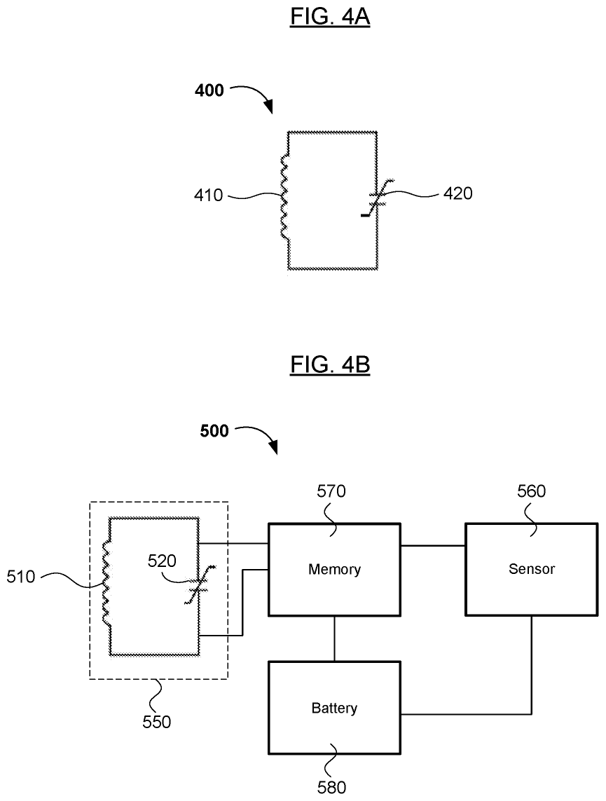

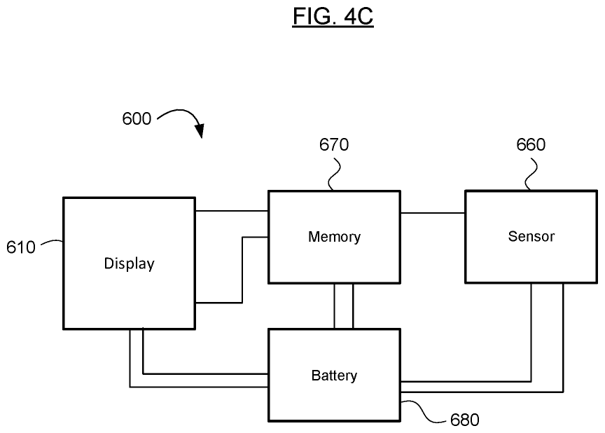

FIGS. 4A-C show exemplary block diagrams 400, 500 and 600 for an EAS tag, wireless device and sensor, respectively, suitable for use in the present invention. FIG. 4A shows an exemplary resonant circuit 400 suitable as a surveillance and/or identification device (e.g., an EAS tag). Generally, the EAS tag 400 includes an inductor (e.g., an inductor coil) 410 and a capacitor 420. The capacitor 420 may be linear (as shown) or non-linear, in which case it may further include a semiconductor layer, which may be on or in contact with at least a portion of the capacitor dielectric layer and/or a capacitor electrode. In some embodiments, the resonant circuit 400 may further comprise a second capacitor coupled to the first capacitor 420.

FIG. 4B shows an exemplary wireless device 500 with a resonant circuit 550 and a sensor 560, suitable for use in the present invention. The resonant circuit 550 includes an inductor 510 and a capacitor 520, and the wireless device 500 further includes a memory 570 and a battery 580 that powers the memory 570 and the sensor 560. Details of the inductor 510 and capacitor 520 are the same as or similar to the descriptions herein of inductors/antennas and capacitors, respectively. The sensor 560 may comprise an environmental sensor (e.g., a humidity or temperature sensor), a continuity sensor (e.g., that determines a sealed, open, or damaged state of the package or container to which the tag is attached), a chemical sensor, a product sensor (e.g., that senses or determines one or more properties of the product in the package or container to which the device 500 is attached), etc., and outputs an electrical signal to the memory 570. This electrical signal corresponds to the condition, state or parameter sensed or detected by the sensor 560. Typically, the memory 570 can be static or dynamic, volatile and/or non-volatile, programmed or programmable, etc. The memory 570 stores a plurality of bits of data, at least one of which corresponds to the condition, state or parameter sensed or detected by the sensor 560, and a subset of which may correspond to an identification number or code for the product to which the device 500 is attached. In some embodiments, the memory 570 and the sensor 560 may be connected to an external ground plane (not shown). The memory 570 outputs a data signal that can be read by an external reader. Thus, the reader is capable of detecting a state, condition or parameter value defined by the sensor, as well as an initial state of the memory 570. Additional circuitry can be added to the circuit 500 to change the state of the memory 570.

FIG. 4C shows an exemplary circuit 600 for a “smart label,” with a sensor 660 and a display or display panel 610 suitable for use in the present invention. The circuit 600 also includes a memory 670 and a battery 680 that powers the display 610, the memory 670, and the sensor 660. Details of the memory 670, the battery 680, and the sensor 660 are as described herein (e.g., with regard to FIG. 4B). Connections between the battery 680 and the display 610, the memory 670, and the sensor 660 may include two or more wires or traces on a substrate. The display 610 is an output device configured to display a readout of signals and/or information from the memory 670. Generally, the display 610 may include an analog or digital display, a full-area 2-dimensional display, and/or a three-dimensional display, but is not limited thereto. Connections between the sensor 660 and the memory 670 may include one or more wires or traces, and the connection between the memory 670 and the display 610 may include two or more wires or traces.

### CONCLUSION

The present invention advantageously improves and/or enables various attachment techniques, such as plating or printing solder bumps or contact pads on or over aluminum attach pads having printed palladium thereon, and attaching the same to a backplane (which may be solder-available) using a conductive adhesive, a low temperature solder, or a self-assembly material. The present invention advantageously enables formation of high-quality ohmic contacts to relatively thick aluminum layers and/or pads, as well as formation of relatively large pads or bumps on the aluminum pads/layers and the adjacent passivation layer, which allows larger tolerances during the attach process and enables use of lower resolution, relatively fast pick-and-place processes. In addition, the present invention advantageously enables plated or printed bump formation, and improves the mechanical smoothness of an antenna and/or inductor and other metal trace(s), as well as the electrical contact between an electronic device and the trace(s), antenna and/or inductor. Furthermore, the present invention reduces the cost and processing time of certain electronic devices and/or wireless tags, such as smart labels and NFC, RF, HF, and UHF tags.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application. It is intended that the scope of the invention be defined by the claims appended hereto and their equivalents.

What is claimed is:

1. A method of manufacturing an electronic device, comprising:
a) forming an electrical device on a first substrate, said electrical device having a plurality of exposed aluminum pads;
b) depositing a passivation layer on said electrical device, said passivation layer exposing said aluminum pads;
c) printing a palladium-containing ink on said aluminum pads;
d) converting said palladium-containing ink to a palladium-containing layer; and
e) forming a conductive pad or bump on said palladium-containing layer.

2. The method of claim 1, wherein said electronic device is a wireless communication device.

3. The method of claim 2, wherein said wireless communication device comprises a near field (NFC), radio frequency (RF), high frequency (HF), very high frequency (VHF), or ultra high frequency (UHF) communication device.

4. The method of claim 1, wherein said electrical device comprises a capacitor, an antenna or an integrated circuit.

5. The method of claim 4, wherein said electrical device comprises the integrated circuit.

6. The method of claim 1, wherein said first substrate comprises a plastic film.

7. The method of claim 6, wherein the plastic film is selected from the group consisting of a polyimide, a polyethylene terephthalate [PET], a polypropylene, a polyethylene naphthalate [PEN], and a glass/polymer laminate.

8. The method of claim 1, wherein said aluminum pads are part of an aluminum foil.

9. The method of claim 1, further comprising printing an aluminum ink to form said exposed aluminum pads.

10. The method of claim 1, wherein depositing said passivation layer comprises blanket depositing said passivation layer and forming via holes over said aluminum pads.

11. The method of claim 10, wherein forming said via holes comprises etching said passivation layer over said attach pads.

12. The method of claim 1, said passivation layer comprises a dielectric layer.

13. The method of claim 12, wherein said dielectric layer comprises a polyimide, an epoxy, silicon nitride, silicon oxynitride, or a doped or undoped silicon oxide.

14. The method of claim 1, wherein printing said palladium-containing ink comprises ink jet printing, gravure printing, screen printing, or offset printing said palladium-containing ink.

15. The method of claim 14, wherein said palladium-containing ink comprises:
a) a palladium salt and/or complex;
b) one or more solvents adapted to facilitate coating and/or printing of the palladium-containing ink; and
c) one or more optional additives that form gaseous or volatile byproducts upon reduction of the palladium salt or complex to elemental palladium.

16. The method of claim 15, wherein said palladium salt and/or complex has the formula PdXₙ or Pd(L)ₚXₙ, where X is a halide, pseudohalide, nitrate, sulfate, alkanoate, cyanate, isocyanate, alkoxide, carboxylate and/or diketonate; n is equal to a formal charge of palladium plus any associated cations that are present, divided by a formal charge of X; L is selected from the group consisting of NH₃, H₂O, CO, NO, Na, H₂S, C₂H₄, C₆H₆, CN, NC, PH₃, PF₃, and volatile O- and/or N-containing organic solvents; and p is an integer equal to a number of coordination sites on palladium, minus the coordination sites occupied by Xₐ.

17. The method of claim 16, further comprising an anion source additive, adapted to facilitate dissolution of said metal salt(s) and/or metal complex(es) in said solvent.

18. The method of claim 17, wherein said anion source additive comprises NH₄X and/or HX.

19. The method of claim 18, wherein X is chloride.

20. The method of claim 18, wherein said palladium salt and/or complex forms substantially only gaseous or volatile byproducts upon reduction of the palladium salt and/or complex to said elemental palladium.

21. The method of claim 15, wherein said solvent comprises H₂O, an organic solvent, a mixture of H₂O and organic solvent(s), or a mixture of organic solvents.

22. The method of claim 21, wherein said palladium salt and/or metal complex comprises a palladium salt, and said palladium salt comprises a palladium halide, a palladium pseudohalide, palladium nitrate, or palladium sulfate.

23. The method of claim 15, wherein said formulation is substantially anhydrous.

24. The method of claim 15, wherein said palladium-containing ink is also printed on said passivation layer near or adjacent to said attach pads.

25. The method of claim 21, wherein said palladium-containing ink comprises palladium chloride, water, and a water-soluble solvent.

26. The method of claim 25, wherein said water-soluble solvent comprises tetrahydrofuran (THF) or ethylene glycol.

27. The method of claim 21, wherein said palladium-containing ink comprises palladium hexadecanoate and an organic solvent.

28. The method of claim 15, wherein converting said palladium-containing ink to said palladium-containing layer comprises drying said palladium-containing ink and curing said palladium-containing ink.

29. The method of claim 28, wherein curing said palladium-containing ink comprises heating said palladium-containing ink in a reducing atmosphere.

30. The method of claim 29, wherein said reducing atmosphere comprises forming gas.

31. The method of claim 30, wherein said palladium-containing ink is heated to a temperature of 100° C. to 250° C.

32. The method of claim 31, wherein said palladium-containing ink is heated to a temperature of 100° C. to 150° C.

33. The method of claim 1, wherein forming said conductive pad or bump comprises depositing a second metal layer on said palladium layer.

34. The method of claim 33, wherein depositing said second metal layer comprises plating said second metal layer on said palladium layer.

35. The method of claim 34, wherein plating said second metal layer forms a plated bump.

36. The method of claim 34, wherein plating said second metal layer comprises electroless plating.

37. The method of claim 36, wherein said second metal comprises nickel or copper.

38. The method of claim 37, wherein said electroless plating comprises immersing said palladium-containing ink in a plating bath at a temperature of 10° C. to 100° C.

39. The method of claim 38, wherein said temperature is 20° C. to 50° C.

40. The method of claim 39, wherein said electroless plating comprises electroless nickel plating.

41. The method of claim 40, further comprising rinsing said device with distilled water.

42. The method of claim 41, further comprising immersion plating gold or tin on said second metal layer.

43. The method of claim 42, wherein depositing said second metal layer comprises printing said second metal layer on said palladium-containing layer.

44. The method of claim 43, wherein said second metal layer comprises a printed bump.

45. The method of claim 44, wherein said printed bump comprises (i) a solder alloy and (ii) a resin material.

46. The method of claim 45, wherein the solder alloy comprises tin and an alloying element selected from bismuth, tin, silver, copper, zinc and indium.

47. The method of claim 1, further comprising attaching said conductive pad or bump to an antenna on a second substrate.

48. The method of claim 47, further comprising heating said second metal at a temperature of about 100° C. to 250° C.

49. The method of claim 47, wherein said second substrate comprises a plastic film.

50. The method of claim 49, wherein said plastic film comprises polyethylene terephthalate [PET], polypropylene, or polyethylene naphthalate [PEN].

51. The method of claim 47, wherein said aluminum layer has a thickness of at least 5 μm.

52. The method of claim 47, wherein the antenna consists of a single metal layer on the substrate.

53. The method of claim 5, wherein forming the integrated circuit comprises printing one or more layers of the integrated circuit on said first substrate.

54. The method of claim 53, comprising printing a plurality of the layers of the integrated circuit.

55. The method of claim 54, wherein forming the integrated circuit further comprises forming one or more additional layers of the integrated circuit by one or more thin film processing techniques.

56. An electronic device, comprising:
a) a first substrate having an electrical device thereon, said electrical device having a plurality of exposed aluminum pads;
b) a passivation layer on said electrical device, said passivation layer configured to expose said aluminum pads;
c) a printed palladium-containing layer on said aluminum pads; and
d) a conductive pad or bump on said palladium-containing layer.

57. The electronic device of claim 56, wherein said electronic device comprises a wireless communication device.

58. The electronic device of claim 57, wherein the wireless communication device is a near field (NFC), radio frequency (RF), high frequency (HF), very high frequency (VHF), or ultra high frequency (UHF) communication device.

59. The electronic device of claim 58, wherein said electrical device comprises a capacitor, an integrated circuit or an antenna.

60. The electronic device of claim 59, wherein said electrical device comprises said integrated circuit.

61. The electronic device of claim 60, wherein said first substrate comprises a plastic film.

62. The electronic device of claim 61, wherein the plastic film is selected from the group consisting of a polyimide, a polyethylene terephthalate [PET], a polypropylene, a polyethylene naphthalate [PEN], and a glass/polymer laminate.

63. The electronic device of claim 62, wherein said aluminum pads are part of an aluminum foil.

64. The electronic device of claim 63, wherein said aluminum pads comprise printed aluminum pads.

65. The electronic device of claim 64, wherein said passivation layer comprises a dielectric layer.

66. The electronic device of claim 65, wherein said dielectric layer comprises a polyimide, an epoxy, silicon nitride, a silicon oxynitride, or a doped or undoped silicon oxide.

67. The electronic device of claim 66, wherein said printed palladium layer is also on said passivation layer near or adjacent to said aluminum pads.

68. The electronic device of claim 67, wherein said printed palladium-containing layer on said aluminum pads and said passivation layer comprises a redistribution layer.

69. The electronic device of claim 68, further comprises a second metal layer on said palladium-containing layer.

70. The electronic device of claim 69, wherein said second metal comprises a plated second metal layer on said palladium-containing layer.

71. The electronic device of claim 70, wherein said plated second metal layer comprises a plated bump.

72. The electronic device of claim 71, wherein said plated bump comprises an electroless plated bump.

73. The electronic device of claim 71, wherein said second metal layer comprises nickel or copper.

74. The electronic device of claim 73, wherein said second metal layer further comprises a plated gold or tin bump.

75. The electronic device of claim 74, wherein said second metal comprises a printed bump.

76. The electronic device of claim 75, wherein said printed bump comprises a solder alloy.

77. The electronic device of claim 76, further comprises a resin material.

78. The electronic device of claim 76, wherein said solder alloy comprises tin and an alloying element selected from bismuth, tin, silver, copper, zinc, and indium.

79. The electronic device of claim 77, further comprising an antenna on a second substrate, said antenna being attached to said conductive pad or bump.

80. The electronic device of claim 79, wherein said second substrate comprises a plastic film.

81. The electronic device of claim 80, wherein said plastic film comprises polyethylene terephthalate [PET], polypropylene, or polyethylene naphthalate [PEN].

82. The electronic device of claim 79, wherein said antenna has a thickness of at least 5 μm.

83. The electronic device of claim 82, wherein said antenna is configured to (i) receive and (ii) transmit or broadcast wireless signals.

84. The electronic device of claim 83, wherein the antenna consists of a single metal layer.

85. The electronic device of claim 84, said antenna further comprises a second palladium-containing layer.

86. The electronic device of claim 70, wherein the integrated circuit comprises one or more printed integrated circuit layers.

87. The electronic device of claim 86, wherein the integrated circuit further comprises one or more thin films.
